(19) United States
(12) Patent Application Publication
(10) Pub. No.: US 2016/0111406 A1
(43) Pub. Date: Apr. 21, 2016

(54) TOP-SIDE INTERCONNECTION SUBSTRATE FOR DIE-TO-DIE INTERCONNECTION

(71) Applicant: GlobalFoundries Inc., Grand Cayman (KY)

(72) Inventor: Tak Ming Mak, Union City, CA (US)

(73) Assignee: GlobalFoundries Inc.

(21) Appl. No.: 14/517,397

(22) Filed: Oct. 17, 2014

(51) Int. Cl. H01L 25/18; H01L 21/48; H01L 25/065; H01L 23/538; H01L 25/00; H01L 23/00

(52) U.S. Cl. CPC H01L 25/18; H01L 25/50; H01L 24/19; H01L 24/25; H01L 24/82; H01L 25/0657; H01L 25/0652; H01L 23/5386; H01L 21/4853; H01L 23/5389; H01L 2225/06513; H01L 2225/06517; H01L 2224/24137; H01L 2224/24226; H01L 2924/1434; H01L 2924/1432

(57) ABSTRACT

At least one method, apparatus and system disclosed involves a multi-die integrated circuit device. A first substrate portion having a first height is formed. A first device over the first substrate portion is formed. A second substrate portion having a second height is formed. A second device is formed over the second substrate portion. An interconnect substrate feature is formed above the first and second devices. The interconnect substrate is configured to accommodate a plurality of interconnect lines electrically coupling the first and second devices.

### BACKGROUND OF THE INVENTION

1. Field of the Invention

Generally, the present disclosure relates to the manufacture of sophisticated semiconductor devices, and, more specifically, to various methods and structures providing a top-side interconnection substrate for die-to-die interconnection in an integrated circuit chip.

2. Description of the Related Art

The technology explosion in the manufacturing industry has resulted in many new and innovative manufacturing processes. Today's manufacturing processes, particularly semiconductor manufacturing processes, call for a large number of important steps. These process steps are usually vital, and therefore, require a number of inputs that are generally fine-tuned to maintain proper manufacturing control.

The manufacture of semiconductor devices requires a number of discrete process steps to create a packaged semiconductor device from raw semiconductor material. The various processes, from the initial growth of the semiconductor material, the slicing of the semiconductor crystal into individual wafers, the fabrication stages (etching, doping, ion implanting, or the like), to the packaging and final testing of the completed device, are so different from one another and specialized that the processes may be performed in different manufacturing locations that contain different control schemes.

Generally, a set of processing steps is performed on a group of semiconductor wafers, sometimes referred to as a lot, using semiconductor-manufacturing tools, such as exposure tool or a stepper. As an example, an etch process may be performed on the semiconductor wafers to shape objects on the semiconductor wafer, such as polysilicon lines, each of which may function as a gate electrode for a transistor. As another example, a plurality of metal lines, e.g., aluminum or copper, may be formed that serve as conductive lines that connect one conductive region on the semiconductor wafer to another.

Often, a single electronic chip package may contain a plurality of separate integrated circuit devices. For example, manufacturers have often placed processors and memory components on the same chip package. In this manner, faster communications between processor and memory may be achieved. One of the limitations of placing multiple devices on a single package is the amount of interconnections between the devices. The greater the memory size, the greater the number of interconnections that is needed between the processor and the memory devices. Similarly, the more complex the processor, the greater the required number of interconnections.

FIG. 1 illustrates a block diagram depiction of a prior art device package that comprises a central processing unit (CPU) and a plurality of memory devices (e.g., DRAMs). FIG. 1 illustrates a substrate 110 of a device package, on which a CPU 120 and a plurality of memory devices 130 are formed. The memory devices 130 are electrically coupled to the CPU 120 via interconnection lines 140. Each of the memory devices 130 of FIG. 1 may represent a stack of memory devices, such as DRAMs. The greater the stack, the greater the number of interconnection lines 140. In order to accommodate a large number of interconnection lines, a high-density substrate is generally used. Designers have implemented a silicon interposer 150 in the area between the memory devices 130 and the CPU 120 in order to accommodate high density signal lines.

FIG. 2 illustrates a stylized cross-sectional depiction of the prior art device package comprising a plurality of integrated circuit devices of FIG. 1. The device package comprises the substrate 110 upon which a plurality of small metal connection features or small “bumps” 220, which acts as an electrical connection conduit for receiving and providing electrical signals. The CPU 120 and the memory devices 130 (e.g., a high-bandwidth memory (HBM) stack) are electrically coupled to the substrate 100 via the silicon interposer 150. Electrical lines traverse the silicon interposer 150 to the small bumps 220 (with through silicon via (TSV)), which are in turn connected to lines that traverse through the substrate 110 onto large metal connection points or large “balls,” flats, or pins 210, with plated through holes on the outside of the device package.

The memory device 130 on the HBM stack may be interconnected via micro bumps 230. The interconnection between the silicon interposer 150 and the HBM stack is also facilitated by medium bumps 235 (e.g., C4 bumps). The high density signal lines (interconnection lines 140) between the HBM stack and the CPU 120 are provided through the silicon interposer 150 via micro bumps 230. One of the problems associated with the prior art is that the fabrication of the silicon interposer 150 has limitations based upon the reticles used in the processes, e.g., photolithography processes. This may limit the size of the processor and the memory devices that may be formed in the device package. Generally, the market demands larger and larger processors and multiple memory stacks. However, due to the limitations of the silicon interposer 130, it is increasingly difficult to place larger processors and more than two memory stacks on a single silicon interposer 130.

In order to reduce the problems associated with the use of silicon interposers, some designers have implemented a so-called silicon bridge along with a smaller silicon interposer to accommodate high-density signals between devices in a device package. FIG. 3 illustrates a stylized depiction of a prior art silicon bridge implementation of multiple devices in a device package. The substrate 110 may comprise a CPU 120 and memory devices 130. In this example, the interconnection lines 140 between the CPU 120 and the memory device 130 are formed to traverse the silicon bridge 310. The silicon bridge 310 is a silicon substrate that accommodates high density electrical signal lines. An example of a silicon bridge implementation is disclosed in U.S. Pat. No. 8,227,904.

FIG. 4 illustrates a stylized cross-sectional depiction of the prior art device package of FIG. 3. FIG. 4 shows that the CPU 120 and the memory device 130 are positioned above the substrate 110. The interconnection lines 140 between the CPU 120 and the memory device 130 (memory stack) are provided through the silicon bridge 310 that is position on a silicon interposer 420. The micro bumps 230 couple the memory device 130 and the CPU 120 onto the silicon bridge 310, while the medium bumps 235 couple them to the substrate 110. Some of the problems associated with the silicon interposer 420 are similar to the problems described above with respect to FIGS. 1 and 2. Further, the solution of FIGS. 3 and 4 includes the problem of accommodating varying die heights between the devices on the device package. For example, the die height for a HBM stack version of the memory device 130 is higher than the die height of the CPU 120. This poses a problem as to positioning multiple devices and providing their interconnection via the silicon bridge. The so-called silicon bridge in the prior art may be more accurately described as a silicon subway. The bottom-oriented silicon bridge below is directed to having the same height for the devices placed in the device package, which can be difficult to accomplish. Also, accurately aligning the micro bumps and the connections between the devices 120, 130 and the silicon bridge 310 is also a difficult process, which may cause inefficiencies and errors in process multi-device integrated circuit chips.

The present disclosure may address and/or at least reduce one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods, apparatus and system for providing a multi-die integrated circuit device. A first substrate portion having a first height is formed. A first device over the first substrate portion is formed. A second substrate portion having a second height is formed. A second device is formed over the second substrate portion. An interconnect substrate feature is formed above the first and second devices. The interconnect substrate is configured to accommodate a plurality of interconnect lines electrically coupling the first and second devices.

### BRIEF DESCRIPTION OF THE DRAWINGS

The disclosure may be understood by reference to the following description taken in conjunction with the accompanying drawings, in which like reference numerals identify like elements, and in which:

FIG. 1 illustrates a block diagram depiction of a prior art device package that comprises a processing unit and a plurality of memory stacks;

FIG. 2 illustrates a stylized cross-sectional depiction of the prior art device package comprising a plurality of integrated circuit devices of FIG. 1;

FIG. 3 illustrates stylized depiction of a prior art silicon bridge implementation of multiple devices in a device package;

FIG. 4 illustrates a stylized cross-sectional depiction of the prior art device package of FIG. 3;

FIG. 5 illustrates a stylized depiction of a device package comprising a plurality of integrated circuit devices and topside interconnections, in accordance with embodiments herein;

FIG. 6 illustrates a stylized depiction of a cross-sectional view of the device package, in accordance with embodiments herein;

FIG. 7 illustrates a stylized cross-sectional depiction of a substrate in accordance with embodiments herein;

FIG. 8 illustrates a stylized cross-sectional depiction of a coreless substrate portion of a semiconductor device package, in accordance with embodiments herein;

FIG. 9 illustrates a stylized cross-sectional depiction of a core substrate portion of a semiconductor device package, in accordance with embodiments herein; and

FIG. 10 illustrates a stylized depiction of a system for fabricating a semiconductor device package comprising a topside interconnection substrate, in accordance with embodiments herein; and

FIG. 11 illustrates a flowchart depiction of a method for providing a semiconductor device package comprising a topside interconnection substrate, in accordance with embodiments herein.

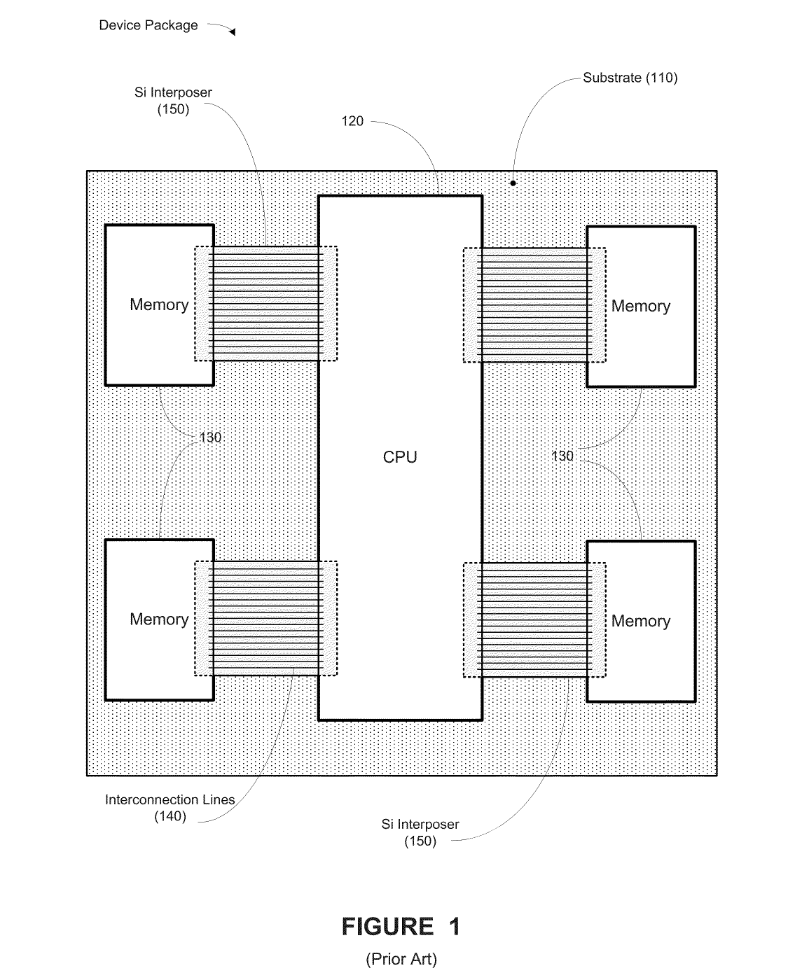

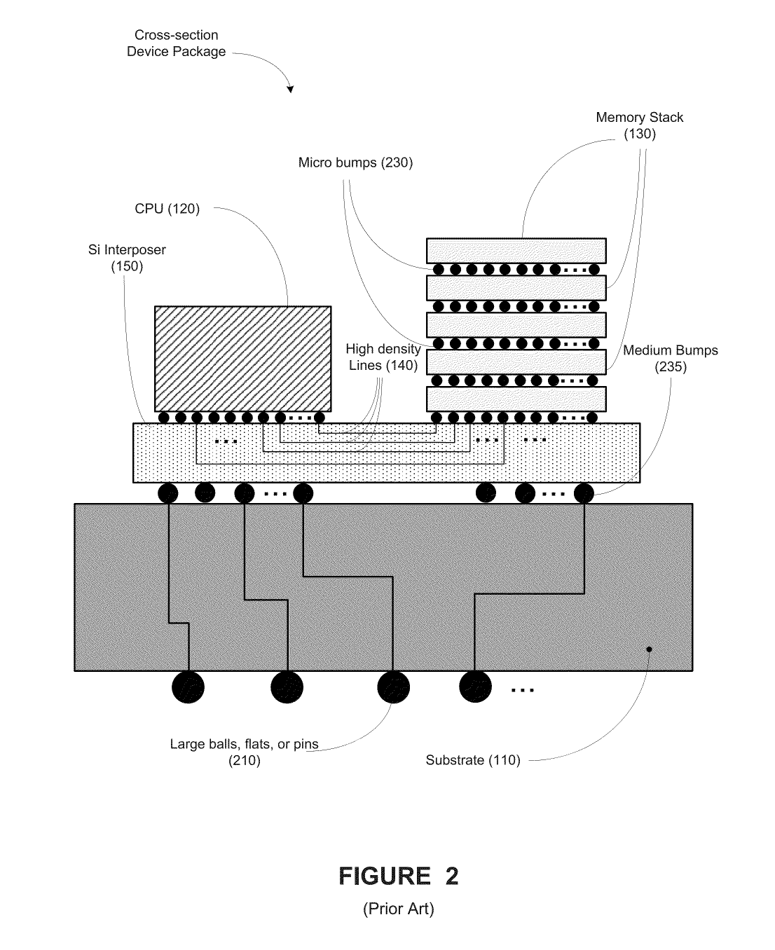

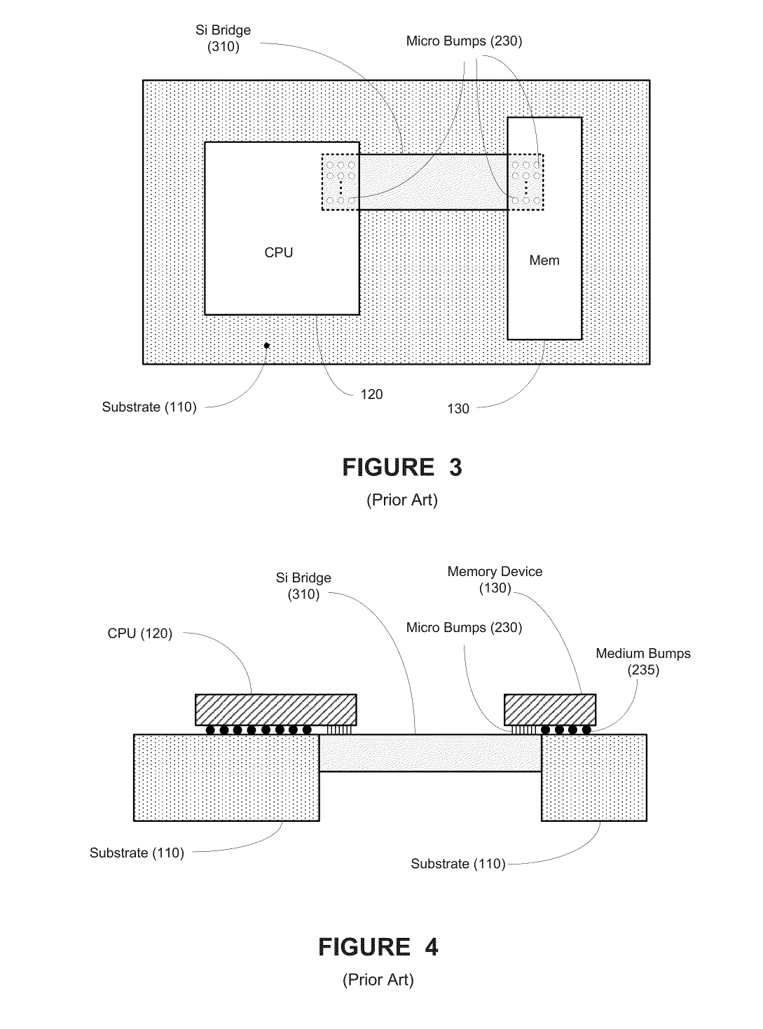

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Embodiments herein provide for high-density die-to-die interconnections in an integrated circuit device. For example, a connection between a 1^{st} device (e.g., a processor) and a 2^{nd} device (e.g., memory device) within a single device package may be provided by an interconnection substrate portion placed on the top side of the processor and the memory device. This interconnection substrate portion may be referred to as a “sky-bridge,” which may be positioned on the top side of the 1^{st} device and the 2^{nd} device, bridging electrical connections between the 1^{st} device 2^{nd} devices. The interconnection substrate portion is capable of accommodating a large number of interconnect signals that provide connections between the 1^{st} and 2^{nd} devices. The interconnections between the 1^{st} and 2^{nd} devices may be provided between the topside of the devices and the bottom side of the interconnection substrate portion to form a topside bridge for the interconnections. In some embodiments, the interconnections may be provided by signal bumps, e.g., micro bumps. The micro bumps may be arranged in a high-density fashion for providing transmission of a large number of electrical signals in a relatively small space. In alternative embodiments, the other types of interconnections may be used in conjunction with the interconnection substrate portion and remain within the spirit and scope of the present disclosure.

In some embodiments, interconnection substrate portion allows for accommodating various heights of the 1^{st} and 2^{nd} devices. For example, a substrate on which the 1^{st} device is fabricated may be adjusted such that the height of the 1^{st} device matches the height of the 2^{nd} device, which in one example, may be a stack of memory device that has a higher height compared to the height of the 1^{st} device.

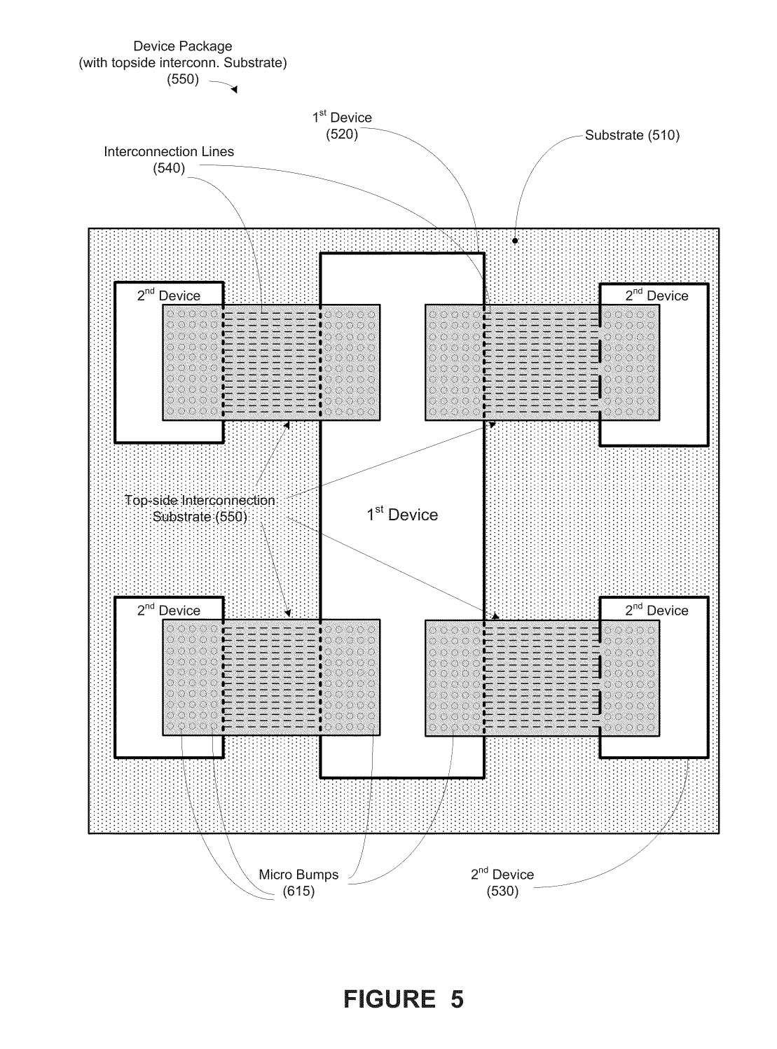

Turning now to FIG. 5, a stylized depiction of a device package (i.e., an integrated circuit chip) comprising a plurality of integrated circuit devices and topside interconnections, in accordance with embodiments herein, is illustrated. A device package 500 may comprise a substrate 510 upon which a plurality of devices and features may be formed. A 1^{st} device 520 (e.g., a processor) and a 2^{nd} device 530 (e.g., a memory device) may be placed (e.g., bonded) on the substrate 510. In some embodiments, a plurality of 2^{nd} devices 530 may be placed (e.g., bonded). The processor may be a central processing unit (CPU), a graphics processing unit (GPU), a network processing unit (NPU), or any type of processor or controller. In one embodiment, each of the 2^{nd} devices 530 of FIG. 5 may represent a stack of devices, such as stack of memory devices (e.g., DRAM stacks).

The 1^{st} and 2^{nd} devices may be interconnected via interconnection lines 540. The interconnection lines 540 may be housed in a topside interconnection substrate 550, which is positioned on the top sides of the 1^{st} and 2^{nd} devices. The topside interconnection substrate 550 is capable of accommodating a high density of interconnect lines between the 1^{st} and 2^{nd} devices. Moreover, the 2^{nd} device stack 530 may be of a higher height compared to the height of the 1^{st} device 520. In order to provide a straight path for the interconnect lines 540, the height of the portion of the substrate 510 below the 1^{st} device may be increased such that the height of the topsides of both the 1^{st} and 2^{nd} devices are substantially the same. In this manner a variety of device stacks, e.g., DRAM memory stack may be accommodated by the device package 500. Accordingly, a large variety of memory sizes and large amounts of interconnect lines 540 can be placed on the substrate 510. Thus, a large amount of memory (e.g., memory stacks) and large processors may be implemented in a device package. In this manner, the limitations of the prior art interconnections, such as the size restrictions and alignments issues with regarding to the silicon bridge and the silicon interposer, are reduced.

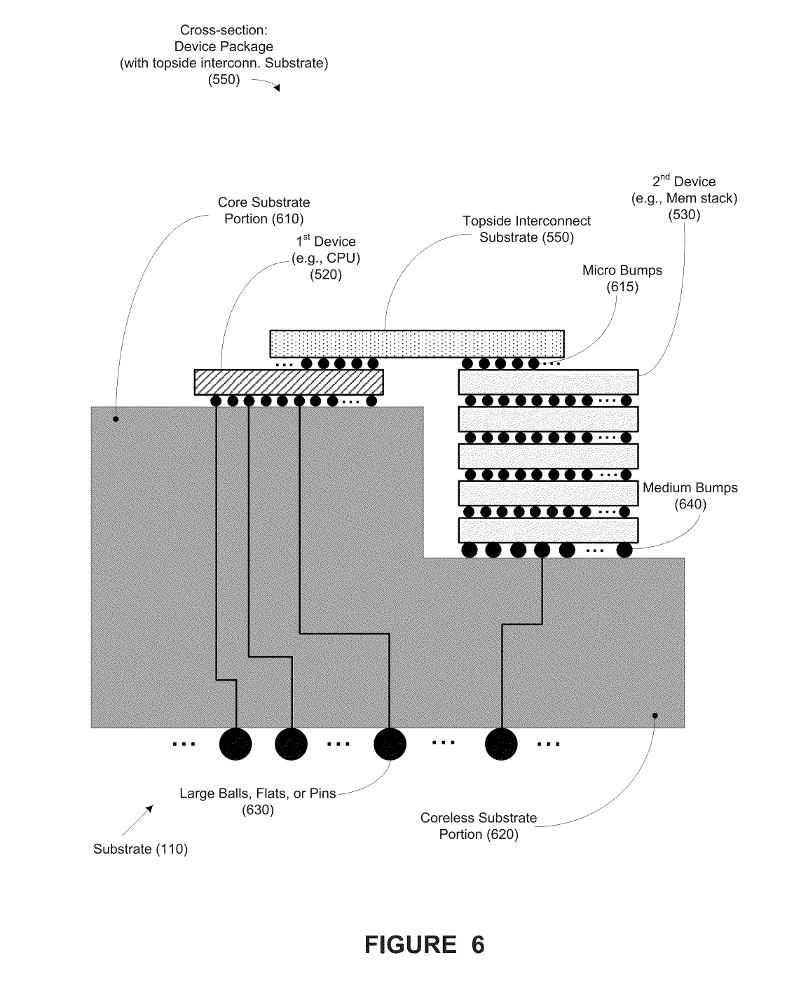

Turning now to FIG. 6, a stylized depiction of a cross-sectional view of the device package, in accordance with embodiments herein, is illustrated. In one embodiment, the substrate illustrated in FIG. 6 comprises two sections, a thicker core substrate portion/section 610 and a coreless substrate portion/section 620. The core substrate section 610 comprises a core within the substrate on which the 1^{st} device 520 may be bonded. The 2^{nd} device (e.g., a memory stack) 530 may be bonded on the coreless substrate section 620. As shown in FIG. 6, the 1^{st} and 2^{nd} devices 520, 530 may be electrically coupled via the topside interconnection substrate 550.

The respective heights of the top-side portions of the 1^{st} and 2^{nd} devices 520, 530 may be equalized by adjusting the height of the core substrate section 610 for accommodating the topside interconnection substrate 550. The substrate of FIG. 6 may comprise a plurality of large interconnection points, e.g., large balls, flats, or pins 630, which provide electrical signal coupling between the 1^{st} and 2^{nd} devices 520, 530 and signal interfaces outside the device package 500. Although the interconnection points 630 are exemplified as balls, those skilled in the art would appreciate that alternatively, they may be flats or pins. A plurality of medium bumps 640 (e.g., C4 bumps) may provide interconnections between the substrate and the 1^{st} and 2^{nd} devices 520, 530. During the bonding process, the surface tension of the melted solder utilized in the bonding process may help to align the devices 520, 530. The C4 bumps provide for efficient and quality x-y alignment of the die stack of the 1^{st} and/or 2^{nd} devices 520, 530. Moreover, more of the underside C4 bumps may be assigned as power bumps and may provide improved delivery of power to the 1^{st} and/or 2^{nd} devices 520, 530.

In one embodiment, both the 1^{st} and 2^{nd} devices 520, 530, may be fabricated such that signals from them can be accessed on the topside of the devices 520, 530. A plurality of micro bumps 615 may be coupled to the topside of the devices 520, 530 to allow access to signals from them. The micro bumps 615 may be electrically coupled to the bottom of the topside interconnection substrate 550. High-density interconnect lines 540 (FIG. 5) within the topside interconnection substrate 550 provide for electrical coupling between the 1^{st} and 2^{nd} devices 520, 530.

The topside interconnection substrate 550 may be comprised of silicon material and may be efficiently accommodated by a thermal interface material (TIM) to spread and/or dissipate heat, resulting in minimal impact to thermal dissipation. The topside interconnection substrate 550 may be positioned at a level configuration above the 1^{st} and 2^{nd} devices 520, 530. Therefore, the top portion of the topside interconnection substrate 550 is substantially flat can efficiently interface with a TIM for thermal dissipation.

Each of the 1^{st} and 2^{nd} devices 520, 530 may be connected to the topside interconnection substrate 550 via the micro bumps 615. The micro bumps 615 are located at the bottom of the topside interconnection substrate 550 and the top of the 1^{st} and 2^{nd} devices 520, 530. A large number of interconnection lines 540 may be provided to interconnect the respective micro bumps 615 of the 1^{st} and 2^{nd} devices 520, 530. The interconnection lines 540 are located within the topside interconnection substrate 550. The interconnections between various die in a package is provided by the topside interconnection substrate 550 The topside interconnection substrate 550 allows for interconnecting multiple die without resorting to the use of the large silicon interposers or in-substrate embedded silicon bridge. Embodiments herein provide for fabricating larger processors and memory stacks may be fabricated into the device package 500.

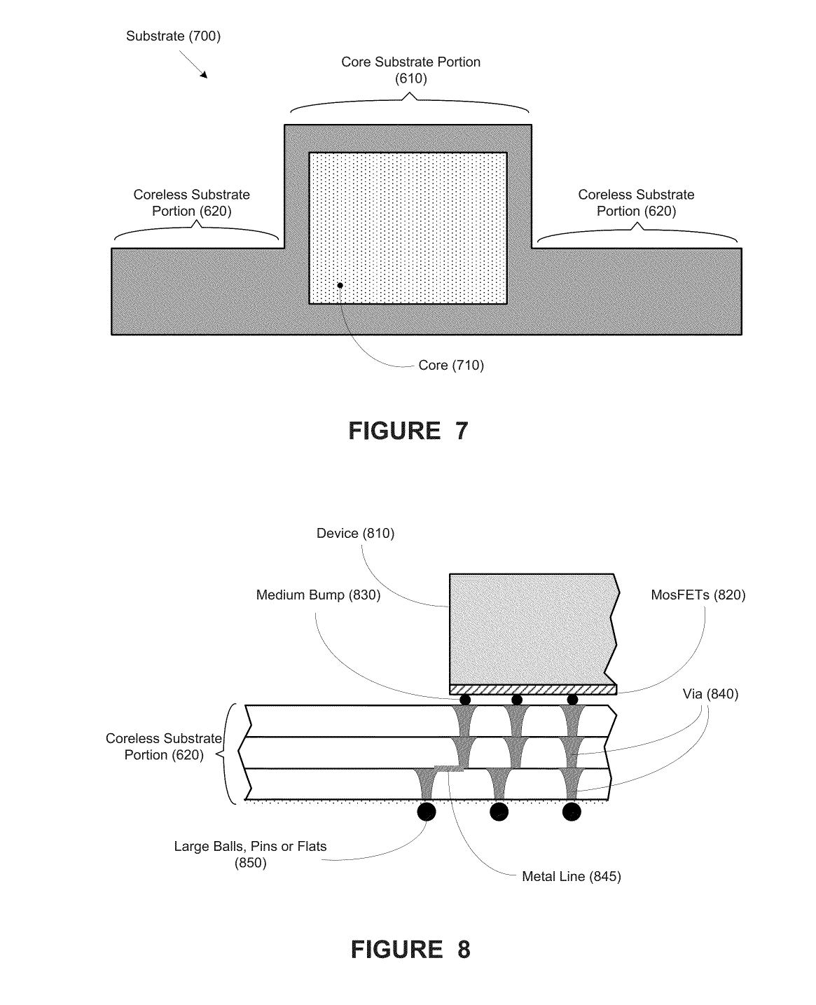

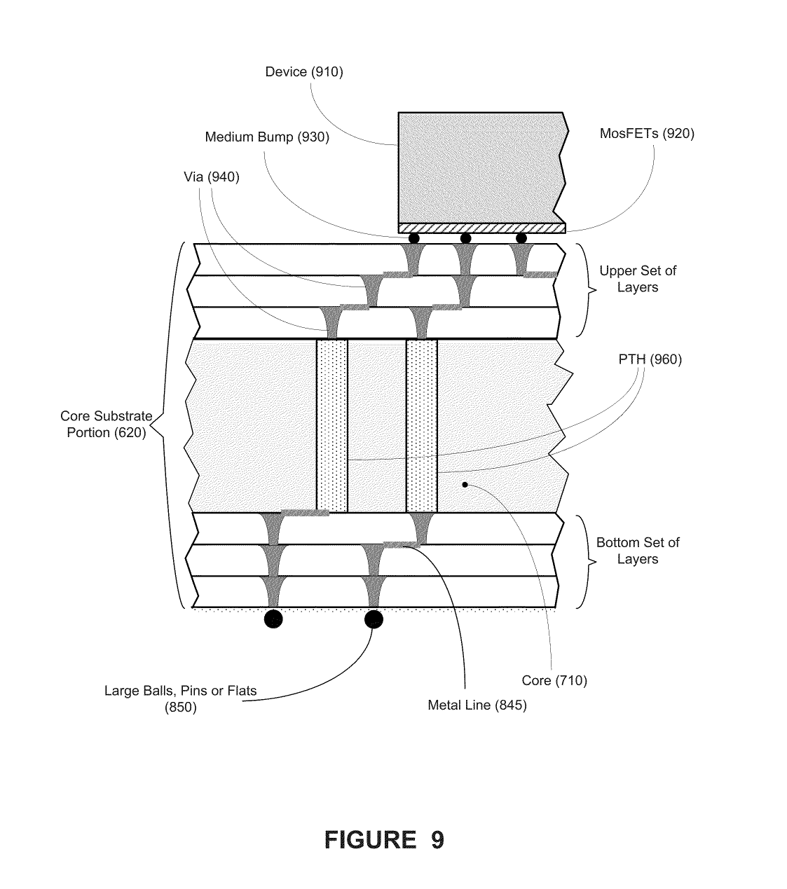

Turning now to FIG. 7, a stylized cross-sectional depiction of a substrate in accordance with embodiments herein, is illustrated. A substrate 700 may comprise one or more core substrate section 610 and one or more coreless substrate section 620. The core substrate section may comprise a core 710 and multiple layers of built-up layers for signal routing and inter-layer connections (FIG. 9). The core 710 may be comprised of various materials, such as glass cloth. The size of the core 710 may be adjusted to accommodate the height of a stack of devices (e.g., a DRAM stack) such that the height of a device fabricated on the core substrate section 610 is the same as the height of the stack of devices that is fabricated on the coreless substrate section 620.

Turning now to FIG. 8, a stylized cross-sectional depiction of a coreless substrate portion of a semiconductor device package, in accordance with embodiments herein, is illustrated. The coreless substrate section 620 may comprise a plurality of layers comprising a plurality of vias 840 and metal lines 845. A device 810, which may represent a device stack (e.g., a DRAM stack) may be placed (e.g., bonded) on the surface of the coreless substrate section 620. The device 810 may be electrically coupled to the coreless substrate section 620 through medium bumps 830 (e.g., C4). In one embodiment, the medium bumps 830 may be coupled to a plurality of MOSFETs 820 formed in the device 810. As an example, a signal from a medium bump 830 may be coupled to one or more vias 840 in consecutive layers. This via 840 may be connected to the metal line 845, which in turn, is connected to another via in the layer below, wherein that via is coupled to a large ball, flat, or pin 850.

Turning now to FIG. 9, a stylized cross-sectional depiction of a core substrate portion of a semiconductor device package, in accordance with embodiments herein, is illustrated. The core substrate section 630 may comprise a plurality of layers comprising a plurality of vias 940 and metal lines 945. Further, below a plurality of layers, a core 710 may be positioned, followed by another plurality of layers. The core 710 may comprise a plurality of plate-through holes (PTHs) 960 such that signals from the top plurality of layers traverse through the core 710 to the bottom plurality of layers.

A device 910, which may represent a processor, may be placed (e.g. bonded) on the surface of the core substrate section 630. The device 910 may be electrically coupled to the core substrate section 630 through medium bumps 930 (e.g., C4). In one embodiment, the medium bumps 930 (e.g. C4 bumps) may be coupled to a plurality of MOSFETs 920 formed in the device 910.

As an example, a signal from a medium bump 930 may be coupled to one or more vias 940 in consecutive layers. This via 940 may be connected to the metal line 945, which in turn, is connected to another via 940 in the layer below, wherein that via 940 is coupled to a plate-through hole (PTH) 960 in the core 710. The signal from the PTH 960 may be coupled to a via 940 or a metal line 945 that is connected to another via 940. The signal may be traverse from the upper set of layers through the core 710 through the PTHs 960, into the bottom set of layer. Vias 950 and metal lines 945 may link the signals from the PTHs 960 to the bottom set of layers and onto the large balls, flats, or pins 950. Using the core substrate and coreless substrates 610, 620, devices and device stacks of varying heights may be fabricated wherein their respective top sides are at the same height, while their interconnections are provided by the topside interconnect substrate 550 (FIG. 5). Those skilled in the art having benefit of the present disclosure would appreciate that the placement of various devices on the core substrate portion 630 and the coreless substrate portion 620 portion may be performed using a variety of processes (e.g., bonding) and remain within the spirit and scope of embodiments herein.

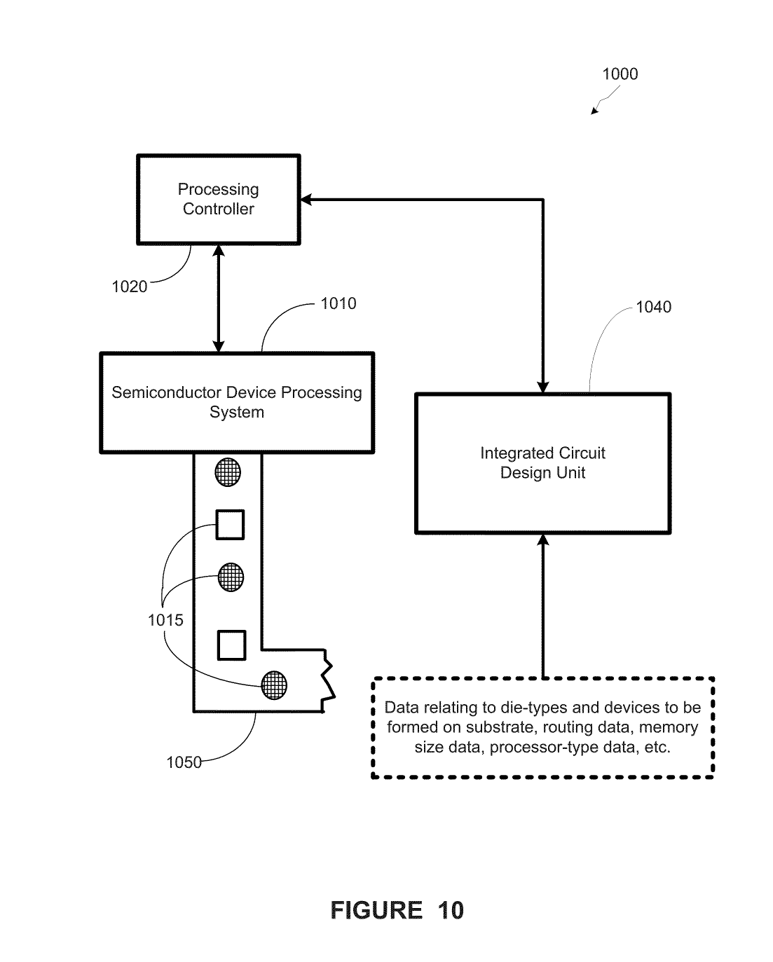

Turning now to FIG. 10, a stylized depiction of a system for fabricating a semiconductor device package comprising a topside interconnection substrate, in accordance with embodiments herein, is illustrated. The system 1000 of FIG. 10 may comprise a semiconductor device processing system 1010 and an integrated circuit design unit 1040. The semiconductor device processing system 1010 may manufacture integrated circuit devices based upon one or more designs provided by the integrated circuit design unit 1040.

The semiconductor device processing system 1010 may comprise various processing stations, such as etch process stations, photolithography process stations, CMP process stations, etc. One or more of the processing steps performed by the processing system 1010 may be controlled by the processing controller 1020. The processing controller 1020 may be a workstation computer, a desktop computer, a laptop computer, a tablet computer, or any other type of computing device comprising one or more software products that are capable of controlling processes, receiving process feedback, receiving test results data, performing learning cycle adjustments, performing process adjustments, etc.

The semiconductor device processing system 1010 may produce integrated circuits on a medium, such as silicon wafers. The production of integrated circuits by the device processing system 1010 may be based upon the circuit designs provided by the integrated circuits design unit 1040. The processing system 1010 may provide processed integrated circuits/devices 1015 on a transport mechanism 1050, such as a conveyor system. In some embodiments, the conveyor system may be sophisticated clean room transport systems that are capable of transporting semiconductor wafers. In one embodiment, the semiconductor device processing system 1010 may comprise a plurality of processing steps, e.g., the 1^{st} process step, the 2^{nd} process set, etc., as described above.

In some embodiments, the items labeled “1015” may represent individual wafers, and in other embodiments, the items 1015 may represent a group of semiconductor wafers, e.g., a “lot” of semiconductor wafers. The integrated circuit or device 1015 may be a transistor, a capacitor, a resistor, a memory cell, a processor, and/or the like. In one embodiment, the device 1015 is a transistor and the dielectric layer is a gate insulation layer for the transistor.

The integrated circuit design unit 1040 of the system 1000 is capable of providing a circuit design that may be manufactured by the semiconductor processing system 1010. The integrated circuit design unit 1040 may be capable of determining the number of devices (e.g., processors, memory devices, etc.) to place in a device package. The integrated circuit design unit 1040 may also determine the size of the memory, and thereby the height of the memory stack. Based upon such details of the devices, the integrated circuit design unit 1040 may determine specifications of the coreless and core substrate portions. Based upon these specifications, the integrated circuit design unit 1040 may provide data for manufacturing a semiconductor device package described herein.

The system 1000 may be capable of performing analysis and manufacturing of various products involving various technologies. For example, the system 1000 may design and production data for manufacturing devices of CMOS technology, Flash technology, BiCMOS technology, power devices, memory devices (e.g., DRAM devices), NAND memory devices, and/or various other semiconductor technologies.

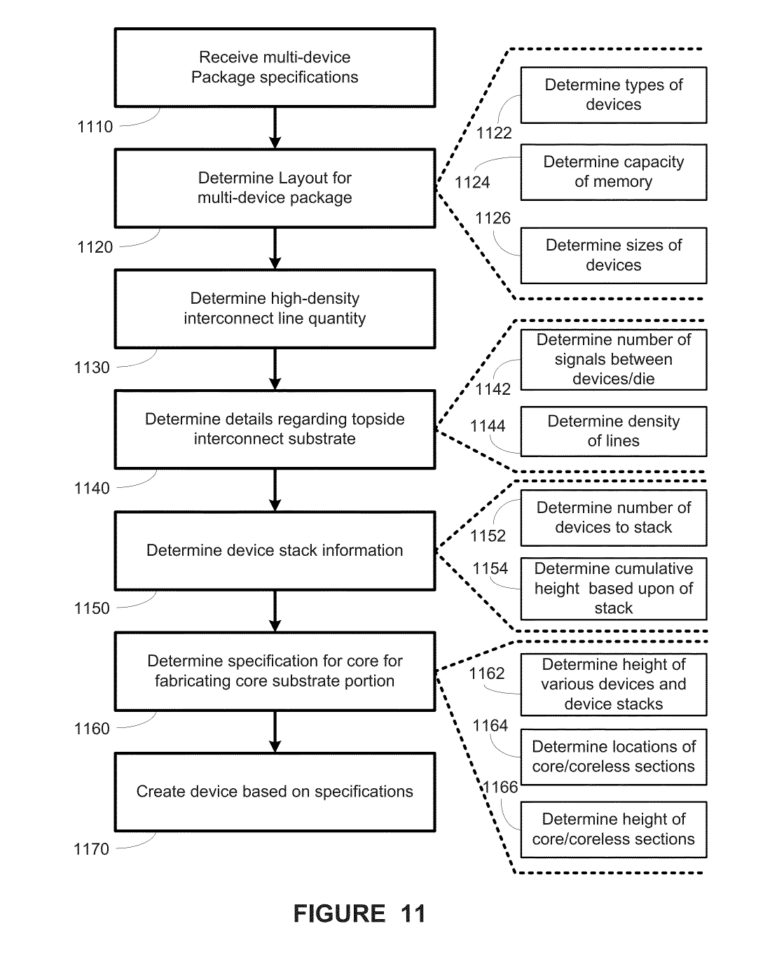

Turning now to FIG. 11, a flowchart depiction of a method for providing a semiconductor device package comprising a topside interconnection substrate, in accordance with embodiments herein, is illustrated. A semiconductor processing system may receive a multi-device package specification (block 1110). The specification may comprise the size of one or more processors, the size of the memory, including the number of memory devices in a memory stack, the number of signals to exit the device, etc.

Based on the specification, the semiconductor processing system may determine the layout of the semiconductor device package (block 1120). This step may include determining the types of devices to place on a substrate (1122). For example, a determination is made whether a processor and a set of memory devices are formed on the substrates for a multi-die device package. A determination may also be made as to the capacity of the memory (block 1124). This information may provide insight as to the amount of memory devices to stack and their cumulative height. Further, the size of the devices may be determined (block 1126). This may include the size of the processor, the memory devices, and their respective footprints.

The system 1000 may then determine quantity of the high-density interconnect lines (block 1130). Based upon this information, a determination may be made as to the specifications for the topside interconnect substrate (block 1140). This step may include determining the number of signals required for interconnecting two devices in the device package (block 1142). Further this step may also include determining the density of the interconnect lines (block 1144). This may provide substantial details for fabricating the topside interconnect substrate, which may be comprised of a high-density silicon substrate.

The system 1000 may also determine the details as to the device stacks (block 1150). This step may include determining the number of devices to stack and/or their individual and cumulative heights (block 1052). This may provide sufficient information to determine the height of the device stack (block 1054).

Based upon the height of the device stack, a determination may be made as to core specifications for the core substrate portion of the substrate (block 1160). This step may include the determining the height of various devices and device stack (block 1162). This may provide information regarding the height differential between the devices (block 1164), which may be used to determine the size and location of the cores for the core substrate portion (block 1166). Based upon the core specification and other information describe above, a device package is fabricated (block 1170).

In this manner, a semiconductor device package comprising a plurality of devices and a topside interconnect substrate, in accordance with embodiments herein.

The system 1000 may be capable of manufacturing and testing various products that include transistors with active and inactive gates involving various technologies. For example, the system 1000 may provide for manufacturing and testing products relating to CMOS technology, Flash technology, BiCMOS technology, power devices, memory devices (e.g., DRAM devices), NAND memory devices, and/or various other semiconductor technologies.

The methods described above may be governed by instructions that are stored in a non-transitory computer readable storage medium and that are executed by, e.g., a processor in a computing device. Each of the operations described herein (e.g., FIGS. 10 and 11) may correspond to instructions stored in a non-transitory computer memory or computer readable storage medium. In various embodiments, the non-transitory computer readable storage medium includes a magnetic or optical disk storage device, solid state storage devices such as flash memory, or other non-volatile memory device or devices. The computer readable instructions stored on the non-transitory computer readable storage medium may be in source code, assembly language code, object code, or other instruction format that is interpreted and/or executable by one or more processors.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method for providing a multi-die integrated circuit device, comprising:
forming a first substrate portion having a first height;
placing a first device over said first substrate portion;
forming a second substrate portion having a second height;
placing a second device over said second substrate portion; and
forming an interconnect substrate feature above said first and second devices, wherein said interconnect substrate being configured to accommodate a plurality of interconnect lines for electrically coupling said first and second devices.

2. The method of claim 1, wherein forming said first substrate portion having said first height comprises:
forming a core substrate; and
wherein said first height is greater than said second height.

3. The method of claim 1, wherein placing said first device over said first substrate portion comprises placing a processing device.

4. The method of claim 1, wherein placing said second substrate portion having said second height comprises placing a coreless substrate.

5. The method of claim 1, wherein forming said interconnect substrate feature above said first and second devices comprises forming a silicon feature adapted to accommodate high density interconnection features.

6. The method of claim 1, wherein placing said second device comprises placing a plurality of memory devices to form a memory stack.

7. The method of claim 6, further comprising determining a number of interconnection lines between said first and second devices, wherein said number of interconnection lines being proportional to the number of said memory devices in said memory stack.

8. The method of claim 7, further comprising forming said interconnection lines in said interconnect substrate feature.

9. The method of claim 8, wherein forming said interconnect substrate feature comprises forming a plurality of metal connection features between said interconnect substrate feature and said first and second devices for coupling said interconnection lines to said first and second devices.

10. The method of claim 9, wherein placing said plurality of memory devices comprises placing a plurality of metal connection features between each of said memory devices for interconnecting said memory devices.

11. The method of claim 1, wherein forming said first substrate portion having a first height comprises forming a core substrate having said first height that is based upon the height of said second device such that the top portion of said first device is in level with the top portion of said second device.

12. An integrated circuit device, comprising:
a substrate comprising a first substrate portion having a first height and a second substrate portion having a second height;
a first device positioned above said first substrate portion;
a second device positioned above said second substrate portion; and
an interconnect substrate feature positioned above said first and second devices, wherein said interconnect substrate feature comprises a plurality of interconnection lines for electrically coupling said first and second devices.

13. The integrated circuit device of claim 12, wherein said first substrate portion comprises a core and wherein said second substrate portion is a coreless substrate portion.

14. The integrated circuit device of claim 12, wherein said first height is greater than said second height, wherein the top portion of said first device is in level with the top portion of said second device.

15. The integrated circuit device of claim 12, wherein said interconnect substrate feature comprises a plurality of high density metal connection features for coupling electrical signal between said first and second devices.

16. The integrated circuit device of claim 12, wherein said first device is a processing device and said second device is a memory stack.

17. The integrated circuit device of claim 16, wherein said memory stack comprises a plurality of memory devices, wherein each of said memory devices comprises a plurality of high density metal connection features for coupling electrical signals between said memory devices.

18. A system, comprising:
a semiconductor device processing system to provide an integrated circuit device, wherein said integrated circuit device comprises:
a substrate comprising a first substrate portion having a first height and a second substrate portion having a second height;
a first device positioned above said first substrate portion;
a second device positioned above said second substrate portion; and
an interconnect substrate feature positioned above said first and second devices, wherein said interconnect substrate feature comprises a plurality of interconnection lines for electrically coupling said first and second devices;
and
a processing controller operatively coupled to said semiconductor device processing system, said processing controller configured to control an operation of said semiconductor device processing system.

19. The system of claim 18, wherein said first substrate portion comprises a core and wherein said second substrate portion is a coreless substrate portion, and wherein said first height is greater than said second height, wherein the top portion of said first device is in level with the top portion of said second device.

20. The system of claim 19, wherein said second device is a memory stack comprising a plurality of memory devices, and wherein said first height and said second height are based upon the height of the memory stack.
